(19) United States
(12) Patent Application Publication
(10) Pub. No.: US 2020/0313699 A1
(43) Pub. Date: Oct. 1, 2020

(54) METHOD AND APPARATUS FOR GENERATING OPTIMAL H MATRIX

(71) Applicant: Suzhou Powercore Technology Co., Ltd., Suzhou (CN)

(72) Inventors: Xingge ZHANG, Suzhou (CN); Chunyang FENG, Suzhou (CN); Gang LIU, Suzhou (CN); Lang PENG, Suzhou (CN); Jing HUANG, Suzhou (CN); Junjie WANG, Suzhou (CN); Lu WANG, Suzhou (CN); Xiaojie ZOU, Suzhou (CN)

(21) Appl. No.: 16/842,046

(22) Filed: Apr. 7, 2020

Related U.S. Application Data
(63) Continuation of application No. PCT/CN2019/096757, filed on Jul. 19, 2019.

(30) Foreign Application Priority Data
Apr. 1, 2019 (CN) 201910258156.2

(51) Int. Cl. H03M 13/00; G06F 11/10

(52) U.S. Cl. CPC H03M 13/616; G06F 11/1076

(57) ABSTRACT

The present application discloses a method and apparatus for generating an optimal H matrix. The method includes steps of: constructing an n*n fundamental matrix according to a preset constraint condition; performing a cyclic shift by taking each row vector of the fundamental matrix as a unit to generate (n−1) expansive matrixes; and generating a target H matrix according to the fundamental matrix and the expansive matrixes. Due to the implementation of the present application, an optimal H matrix is constructed by taking the thought of lowering the space complexity of an H matrix and reducing the hardware cost into consideration on the premise that a single-error-correcting and double-error-detecting function of a Hamming code is not affected; and a cyclic shift method is provided in combination with properties of the optimal H matrix, and a required target optimal H matrix may be formed by regularly expanding the constructed fundamental matrix.

### CROSS REFERENCE TO RELATED APPLICATIONS

This application is a continuation application of International Patent Application No. PCT/CN2019/096757 with an international filing date of Jul. 19, 2019, designating the United States, now pending, and further claims priority benefits to Chinese Patent Application No. 201910258156. 2, filed on Apr. 1, 2019. The contents of all of the aforementioned applications are incorporated herein by reference.

### TECHNICAL FIELD

The present application relates to the technical field of data processing and in particular to a method and apparatus for generating an optimal H matrix.

### BACKGROUND

Data bits may generate errors in a process that a data flow is written into some storage devices (such as RAM and eDRAM) and is read from the storage devices, at the moment, an ECC (Error Checking Correction) code technology is required to detect and correct data bit errors, and a Hamming code serving as an ECC code is widely applied to error correction and detection control of communication and computer storage systems. The current most mainstream Hamming check refers to an SEC-DED (Single-Error-Correcting and Double-Error-Detecting) code for correcting single error and detecting double errors. In high-end workstations or servers, a Hamming error correction and detection module may be adopted to guarantee the accuracy of data, so that the stability of a complete computer system is improved.

In a process of realizing error correction and detection by using the Hamming code, an H matrix (also called check matrix) is required as a guidance to generate a Hamming check code, a synthesis bit and a flip bit for to-be-checked data, and finally, a function of error correction or error detection is performed by virtue of the information, in other words, the most critical factor for affecting properties of the Hamming error correction and detection lies in the generation rule and selection strategy of the H matrix. An optimal H matrix is selected by mainly taking the following three issues into consideration:

firstly, the most basic issue is to require the H matrix to support one-bit correction for transmitted data and also have a function of finding two-bit errors and giving a prompt, so that the possibility that data having errors are transmitted to a next-level module to result in more complex errors is reduced;

secondly, although the Hamming check code may bring stability and safety for a complete computer system, meanwhile, the H matrix serving as an important component in the Hamming code error correction technology may also bring additional space overhead, and therefore, it is expected that the space occupied by the H matrix is small as much as possible on the premise that the function is not affected; and

thirdly, the “1” in each column vector in the H matrix represents for one wire in an actual circuit, in other words, the Hamming weight of the column vector is required to be reduced as much as possible when the optimal H matrix is selected, so that the logic number of hardware is reduced.

However, at present, a set of perfect method for selecting the optimal H matrix in combination with the above-mentioned three issues has not been provided in the implementation of a Hamming check hardware circuit of some engineering projects.

### SUMMARY

For this purpose, embodiments of the present application provide a method and apparatus for generating an optimal H matrix so as to construct an optimal H matrix meeting the above-mentioned various conditions.

According to a first aspect, an embodiment of the present application provides a method for generating an optimal H matrix, including steps of: constructing an n*n fundamental matrix according to a preset constraint condition; performing a cyclic shift by taking each row vector of the fundamental matrix as a unit to generate (n−1) expansive matrixes; and generating a target H matrix according to the fundamental matrix and the expansive matrixes.

In combination with the first aspect, in a first implementation way on the first aspect, the preset constraint condition includes: each column of the fundamental matrix has an odd number of 1; any two columns in the fundamental matrix are different; and a column where a check bit of the fundamental matrix is located has only one 1.

In combination with the first aspect, in a second implementation way on the first aspect, the step of performing the cyclic shift by taking each row vector of the fundamental matrix as the unit includes: sequentially shifting the row vector in an n^{th} row to a first row, and downwards shifting the remaining row vectors; and constructing one of the expansive matrixes by each shift until shifting the row vector in the first row to the last row to construct the (n−1)^{th} row vector.

In combination with the first aspect, in a third implementation way on the first aspect, the step of generating the target H matrix according to the fundamental matrix and the expansive matrixes includes: sequentially stacking the row vectors in the n^{th} rows of the fundamental matrix and the first to (n−1)^{th} expansive matrixes to construct the row vector in the n^{th} row of the target H matrix so as to generate the target H matrix.

According to a second aspect, an embodiment of the present application provides an apparatus for generating an optimal H matrix, including a fundamental matrix construction module configured to construct an n*n fundamental matrix according to a preset constraint condition; an expansive matrix generating module configured to perform a cyclic shift by taking each row vector of the fundamental matrix as a unit to generate (n−1) expansive matrixes; and a target matrix generating module configured to generate a target H matrix according to the fundamental matrix and the expansive matrixes.

In combination with the second aspect, in a first implementation way on the second aspect, the preset constraint condition includes: each column of the fundamental matrix has an odd number of 1; any two columns in the fundamental matrix are different; and a column where a check bit of the fundamental matrix is located has only one 1.

In combination with the second aspect, in a second implementation way on the second aspect, the expansive matrix generating module includes: a shift submodule configured to sequentially shift the row vector in an n^{th} row to a first row and downwards shift the remaining row vectors; and an expansive matrix construction submodule configured to construct one of the expansive matrixes by each shift until shifting the row vector in the first row to the last row to construct the (n−1)^{th} row vector.

In combination with the second aspect, in a third implementation way on the second aspect, the target matrix generating module is specifically configured to: sequentially stack the row vectors in the n^{th} rows of the fundamental matrix and the first to (n−1)^{th} expansive matrixes to construct the row vector in the n^{th} row of the target H matrix so as to generate the target H matrix.

According to a third aspect, an embodiment of the present application provides an electronic device/mobile terminal/server including a memory and a processor communicated with each other, wherein the memory stores a computer instruction, and the processor executes a method for generating the optimal H matrix on the first aspect or in any one implementation way on the first aspect by executing the computer instruction.

According to a fourth aspect, an embodiment of the present application provides a computer readable storage medium, storing a computer instruction configured to make a computer execute a method for generating the optimal H matrix on the first aspect or in any one implementation way on the first aspect.

The embodiments of the present application have the beneficial effects that: according to the method for generating the optimal H matrix in the embodiment of the present application, in consideration of guaranteeing to obtain the minimum logic level and meeting the requirement for least encoded hardware, “1” as little as possible is selected when a fundamental H matrix is constructed, in other words, the number of wires is reduced during corresponding actual hardware logic implementation; and a cyclic shift method may guarantee the phase independence among column vectors and ensure that the number (i.e., the Hamming weight) of “1” in each row is equal, correspondingly, for the specific logic implementation, the simultaneous generation of the check bit and the synthesis bit (syndrome) of the Hamming code may be met, in other words, the number of input interfaces of each XOR logic is the same.

### BRIEF DESCRIPTION OF THE DRAWINGS

The features and advantages of the present application can be more clearly understood with reference to accompanying drawings which are schematic, but should not be understood as a limitation to the present application. In the accompanying drawings:

FIG. 1 shows a flow diagram of a method for generating an optimal H matrix in accordance with an embodiment of the present application;

FIG. 2 shows a process diagram of a cyclic shift of a method for generating the optimal H matrix in accordance with an embodiment of the present application;

FIG. 3 shows a structural schematic diagram of an apparatus for generating an optimal H matrix in accordance with an embodiment of the present application; and

FIG. 4 shows a structural schematic diagram of a computer device in accordance with an embodiment of the present application.

### DETAILED DESCRIPTION

To make the objectives, technical solutions and advantages of embodiments of the present application clearer, the technical solutions in the embodiments of the present application will be clearly and completely described below in combination with the accompanying drawings in the embodiments of the present application. Obviously, the described embodiments are a part of embodiments of the present application, not all the embodiments. Based on the embodiments in the present application, all other embodiments obtained without creative work by those skilled in the art fall within the protection scope of the present application.

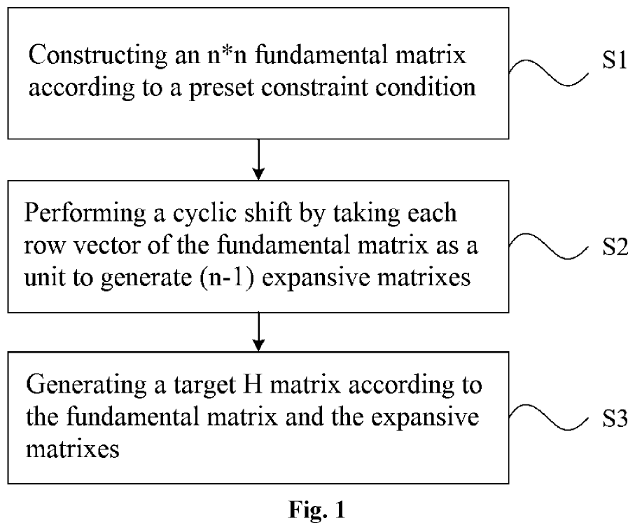

An embodiment of the present application provides a method for generating an optimal H matrix, as shown in FIG. 1, the method for generating the optimal H matrix mainly includes steps of:

S1: an n*n fundamental matrix is constructed according to a preset constraint condition.

In the present application, the thought of the implementation cost of an actual logic circuit is taken into consideration in an H matrix, firstly, the fundamental matrix is constructed, then, a normalized method for generating the optimal H matrix is provided based on constraints for the H matrix, namely the fundamental matrix is expanded to form an optimal target H matrix by using a cyclic shift method.

It is assumed that the number of errors which may be corrected by a Hamming code is t1, and detected errors include (t1+1) to (t1+t2) severe errors, for a single-error-correcting and double-error-detecting function expected to be realized, at the moment, t1 is equal to 1, t2 is equal to 1, and then, the features of the H matrix are derived in combination with a linear algebra correlation theory:

firstly, each column vector has an odd weight, namely each column has an odd number of “1”;

secondly, no any two columns are the same (the linear independence of Hamming codes of column vectors is guaranteed); and

thirdly, a column where a check bit is located (the position of the check bit in the H matrix is equivalent to one unit matrix) has only one “1”.

In addition, in combination with the thought of minimizing the logic circuit implementation cost, the optimal H matrix should also have the features that:

fourthly, the total number of “1” in the H matrix should be the minimum; and

fifthly, the number of “1” in each row of the H matrix should be equal or approach to an average value (namely a value obtained by dividing the number of rows by the number of all 1 in the H matrix) as much as possible.

S2: a cyclic shift is performed by taking each row vector of the fundamental matrix as a unit to generate (n−1) expansive matrixes. For the constructed fundamental matrix, with each row of the fundamental matrix as a unit, row vectors located above are sequentially shifted towards the lower right, and row vectors located below are upwards supplemented, namely the row vector in an n^{th} row is sequentially shifted to a first row, and the remaining row vectors are downwards shifted; and one of the expansive matrixes is constructed by each shift until the row vector in the first row is shifted to the last row to construct the (n−1)^{th} row vector, and finally, the n*n fundamental matrix is expanded to form a target H matrix, and due to the adoption of the cyclic shift method, the expansive matrixes may also meet the first and fifth features of the above optimal H matrix.

S3: the target H matrix is generated according to the fundamental matrix and the expansive matrixes. Specifically, the row vectors in the n^{th} rows of the fundamental matrix and the first to (n−1)^{th} expansive matrixes are sequentially stacked to construct the row vector in the n^{th} row of the target H matrix so as to generate the target H matrix.

When n-bit data are checked, the target H matrix is in a row and column (2+log₂ n)*n, wherein n>=4, in other words, the row is (2+log₂ n), the column is n, and the widths of most of checked data bits in actual integrated circuit storage are larger than or equal to 4 bit.

According to the method for generating the optimal H matrix in the embodiment of the present application, the optimal H matrix is constructed by taking the thought of lowering the space complexity of the H matrix and reducing the hardware cost into consideration on the premise that the single-error-correcting and double-error-detecting function of a Hamming code is not affected; and the cyclic shift method is provided in combination with properties of the optimal H matrix, and the required target optimal H matrix may be formed by regularly expanding the constructed fundamental matrix.

Optionally, in some embodiments of the present application, 64-bit data is taken as an example to illustrate the present application, rather than to limit the present application.

Derived according to the above-mentioned Hamming theory and linear algebra theory, if the single-error-correcting and double-error-detecting function is achieved for the 64-bit data, a Hamming check code is required to have 8 bits, and therefore, the total code length of a linear block code is 72 bits. According to a format of the linear block code, it can be known that the linear block code is (72, 64, 4) which respectively represent for the total code length, source information code length and the minimum Hamming distance of the linear block code. Firstly, if a function of checking the 64-bit data is met, the size of the corresponding H matrix should be 8*64, wherein elements are composed of binary numbers. Due to the properties of the H matrix, namely each column having the odd number of “1”, and in consideration of the hardware logic implementation cost, the fundamental matrix is regarded to be sequentially formed by one “1”, three “1”, five“1” and seven “1”. Firstly, one “1” is related to the linearity of the column (i.e., a certain column in a unit matrix) where the check bit of the matrix is located so as not to be selected. Secondly, for the three “1”, it may be calculated by applying combinational operation that there are C83=8!/((8−3)!*3!)=8*7*6*5*4*3*2*1/45*4*3*2*1)(3*2*1))=56 situations (meeting the second and third features of the optimal H matrix) meeting three “1” in 8-bit data in total.

Due to the adoption of cyclic shift operation (capable of meeting the fourth feature of the optimal H matrix), the 56 situations actually include eight sets of seven base classes, for example, one set includes 0011_1000, 0011_0100, 0011_0010, 0011_0001, 1011_0000, 0010_1010 and 0010_1001, and the target H matrix includes 64 column vectors, and therefore, one base class with five “1” is further required to be added to perform the cyclic shift (such as 1100_0111).

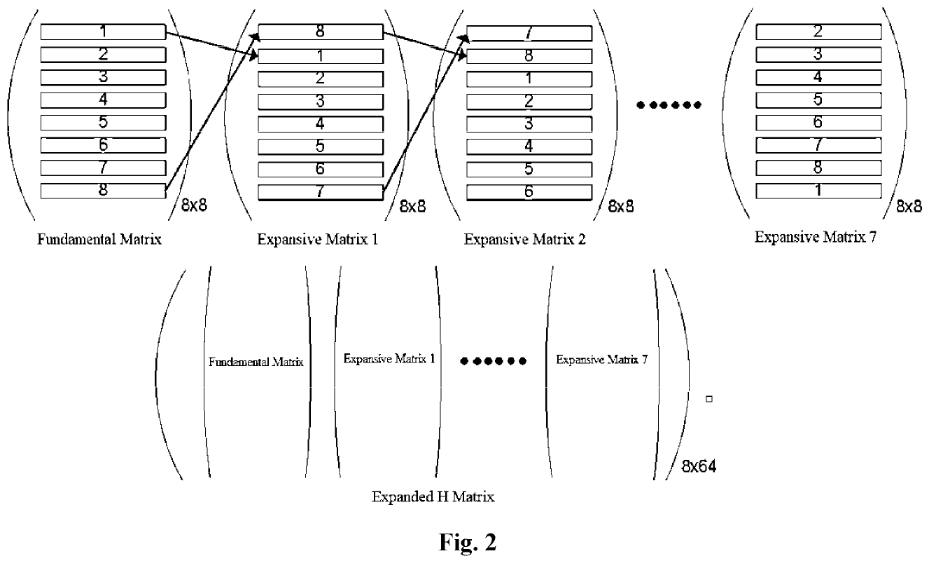

A 8*8 fundamental matrix is constructed based on the above-mentioned conditions, then, with each row of the fundamental matrix as the unit, the row vectors located above are sequentially shifted towards the lower right, and the row vectors located below are upwards supplemented to generate seven expansive matrixes, and the 8*8 fundamental matrix is expanded in combination with the fundamental matrix and the expansive matrixes to form a 8*64 target H matrix, as shown in FIG. 2. By using the cyclic shift method, the expansive matrixes may also meet the first and fifth features of the above optimal H matrix.

According to the method for generating the optimal H matrix in the embodiment of the present application, in consideration of guaranteeing to obtain the minimum logic level and meeting the requirement for least encoded hardware, “1” as little as possible is selected when a fundamental H matrix is constructed, in other words, the number of wires is reduced during corresponding actual hardware logic implementation; and the cyclic shift method may guarantee the phase independence among the column vectors and ensure that the number (i.e., the Hamming weight) of “1” in each row is equal, correspondingly, for the specific logic implementation, the simultaneous generation of the check bit and the synthesis bit (syndrome) of the Hamming code may be met, in other words, the number of input interfaces of each XOR logic is the same.

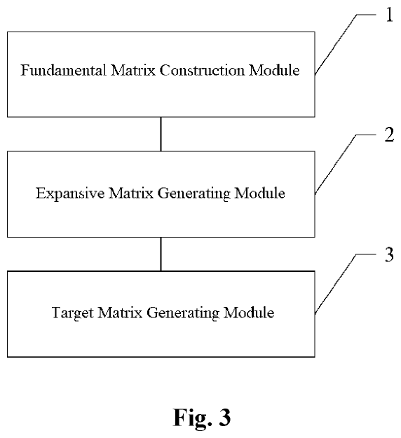

An embodiment of the present application further provides an apparatus for generating an optimal H matrix, as shown in FIG. 3, the apparatus for generating the optimal H matrix includes:

a fundamental matrix construction module 1 configured to construct an n*n fundamental matrix according to a preset constraint condition, wherein the detailed content refers to the related description of the S1 in the embodiment of the above-mentioned method;

an expansive matrix generating module 2 configured to perform a cyclic shift by taking each row vector of the fundamental matrix as a unit to generate (n−1) expansive matrixes, wherein specifically, the expansive matrix generating module 2 includes a shift submodule configured to sequentially shift the row vector in an n^{th} row to a first row and downwards shift the remaining row vectors, and an expansive matrix construction submodule configured to construct one of the expansive matrixes by each shift until shifting the row vector in the first row to the last row to construct the (n−1)^{th} row vector, and the detailed content refers to the related description of the S2 in the embodiment of the above-mentioned method; and

a target matrix generating module 3 configured to generate a target H matrix according to the fundamental matrix and the expansive matrixes, wherein specifically, the row vectors in the n^{th} rows of the fundamental matrix and the first to (n−1)^{th} expansive matrixes are sequentially stacked to construct the row vector in the n^{th} row of the target H matrix so as to generate the target H matrix; the detailed content refers to the related description of the S3 in the embodiment of the above-mentioned method; and when n-bit data are checked, the target H matrix is in a row and column (2+log₂ n)*n, wherein n>=4, in other words, the row is (2+log₂ n), the column is n, and the widths of most of checked data bits in actual integrated circuit storage are larger than or equal to 4 bit.

According to the apparatus for generating the optimal H matrix in the embodiment of the present application, the optimal H matrix is constructed by taking the thought of lowering the space complexity of an H matrix and reducing the hardware cost into consideration on the premise that a single-error-correcting and double-error-detecting function of the Hamming code is not affected; and a cyclic shift method is provided in combination with properties of the optimal H matrix, and a required target optimal H matrix may be formed by regularly expanding the constructed fundamental matrix.

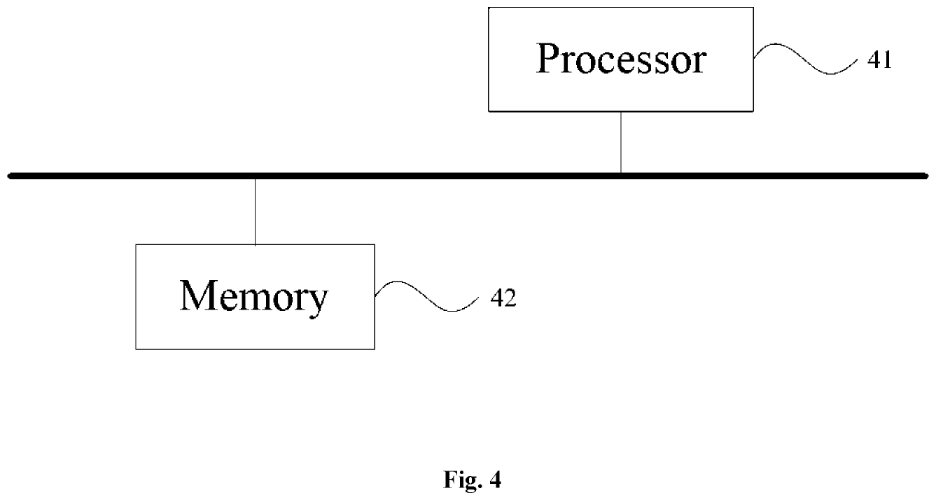

An embodiment of the present application further provides a computer device, as shown in FIG. 4, the computer device may include a processor 41 and a memory 42, wherein the processor 41 and the memory 42 may be connected by a bus or in other ways, and FIG. 4 is described by taking bus connection as an example.

The processor 41 may be a CPU (Central Processing Unit). The processor 41 may also be other general-purpose processor, a DSP (Digital Signal Processor), an ASIC (Application Specific Integrated Circuit), an FPGA (Field-Programmable Gate Array) or chips such as other programmable logic devices, a discrete gate or transistor logic device and a discrete hardware component or a combination of the above-mentioned chips.

As a non-transient computer readable storage medium, the memory 42 may be configured to store non-transient software programs, non-transient computer executable programs and modules such as corresponding program instructions/modules (such as the fundamental matrix construction module 1, the expansive matrix generating module 2 and the target matrix generating module 3 as shown in FIG. 3) in the method for generating the optimal H matrix in the embodiment of the present application. By operating the non-transient software programs, instructions and modules stored in the memory 42, various functional applications and data processing of the processor 41 are executed, namely the method for generating the optimal H matrix in the embodiment of the above-mentioned method is realized.

The memory 42 may include a storage program area and a storage data area, wherein the storage program area may store operation system and application programs required by at least one function; and the storage data area may store data created by the processor 41. In addition, the memory 42 may include a high-speed random access memory and may further include a non-transient memory such as at least one disk memory device, a flash memory device or other non-transient solid memory devices. In some embodiments, the memory 42 optionally includes memories remotely arranged relative to the processor 41, and the remote memories may be connected to the processor 41 via networks. Examples of the above-mentioned networks include, but are not limited to an Internet, Intranet, a local area network, a mobile communication network and a combination thereof.

The one or more modules are stored in the memory 42, and the method for generating the optimal H matrix in the embodiments as shown in FIG. 1-FIG. 2 is executed when the one or more modules are executed by the processor 41.

The specific details of the above-mentioned computer device may be understood by correspondingly referring to the corresponding related description and effects in the embodiments as shown in FIG. 1-FIG. 2, which are not described herein.

It may be understood by those skilled in the art that all or parts of processes in the method in the above-mentioned embodiment may be completed by computer program instruction related hardware, the program may be stored in the computer readable storage medium, and the processes of the embodiment of each of the above-mentioned methods may be included when the program is executed, wherein the storage medium may be a diskette, an optical disc, an ROM (Read-Only Memory), RAM (Random Access Memory), a flash memory, an HDD (Hard Disk Drive) or an SSD (Solid-State Drive) and the like; and the storage medium may also include a combination of the above-mentioned memories.

Although the embodiments of the present application are described in combination with the accompanying drawings, various modifications and variations can be made by those skilled in the art without departing from the spirit and scope of the present application, and such modifications and variations fall within the scope defined by the appended claims.

What is claimed is:

1. A method for generating an optimal H matrix, comprising steps of:
constructing an n*n fundamental matrix according to a preset constraint condition;
performing a cyclic shift by taking each row vector of the fundamental matrix as a unit to generate (n−1) expansive matrixes; and
generating a target H matrix according to the fundamental matrix and the expansive matrixes.

2. The method for generating the optimal H matrix of claim 1, wherein the preset constraint condition comprises:
each column of the fundamental matrix has an odd number of 1;
any two columns in the fundamental matrix are different; and
a column where a check bit of the fundamental matrix is located has only one 1.

3. The method for generating the optimal H matrix of claim 1, wherein the step of performing the cyclic shift by taking each row vector of the fundamental matrix as the unit comprises:
sequentially shifting the row vector in an n^{th} row to a first row, and downwards shifting the remaining row vectors; and
constructing one of the expansive matrixes by each shift until shifting the row vector in the first row to the last row to construct the (n−1)^{th} row vector.

4. The method for generating the optimal H matrix of claim 1, wherein the step of generating the target H matrix according to the fundamental matrix and the expansive matrixes comprises:
sequentially stacking the row vectors in the n^{th} rows of the fundamental matrix, and the first to (n−1)^{th} expansive matrixes to construct the row vector in the n^{th} row of the target H matrix so as to generate the target H matrix.

5. A computer device, comprising:
a memory and a processor communicated with each other,
wherein the memory stores a computer instruction, and the processor executes the computer instruction to perform a method for generating the optimal H matrix that comprises steps of
constructing an n*n fundamental matrix according to a preset constraint condition;
performing a cyclic shift by taking each row vector of the fundamental matrix as a unit to generate (n−1) expansive matrixes; and
generating a target H matrix according to the fundamental matrix and the expansive matrixes.

6. The computer device of claim 5, wherein the preset constraint condition comprises:
each column of the fundamental matrix has an odd number of 1;
any two columns in the fundamental matrix are different; and
a column where a check bit of the fundamental matrix is located has only one 1.

7. The computer device of claim 5, wherein the step of performing the cyclic shift by taking each row vector of the fundamental matrix as the unit comprises:
sequentially shifting the row vector in an n^{th} row to a first row, and downwards shifting the remaining row vectors; and
constructing one of the expansive matrixes by each shift until shifting the row vector in the first row to the last row to construct the (n−1)^{th} row vector.

8. The computer device of claim 5, wherein the step of generating the target H matrix according to the fundamental matrix and the expansive matrixes comprises:
sequentially stacking the row vectors in the n^{th} rows of the fundamental matrix, and the first to (n−1)^{th} expansive matrixes to construct the row vector in the n^{th} row of the target H matrix so as to generate the target H matrix.

9. A computer readable storage medium, storing a computer instruction configured to make a computer execute a method for generating the optimal H matrix that comprises steps of
constructing an n*n fundamental matrix according to a preset constraint condition;
performing a cyclic shift by taking each row vector of the fundamental matrix as a unit to generate (n−1) expansive matrixes; and
generating a target H matrix according to the fundamental matrix and the expansive matrixes.

10. The computer readable storage medium of claim 9, wherein the preset constraint condition comprises:
each column of the fundamental matrix has an odd number of 1;
any two columns in the fundamental matrix are different; and
a column where a check bit of the fundamental matrix is located has only one 1.

11. The computer readable storage medium of claim 9, wherein the step of performing the cyclic shift by taking each row vector of the fundamental matrix as the unit comprises:
sequentially shifting the row vector in an n^{th} row to a first row, and downwards shifting the remaining row vectors; and
constructing one of the expansive matrixes by each shift until shifting the row vector in the first row to the last row to construct the (n−1)^{th} row vector.

12. The computer readable storage medium of claim 9, wherein the step of generating the target H matrix according to the fundamental matrix and the expansive matrixes comprises:
sequentially stacking the row vectors in the n^{th} rows of the fundamental matrix, and the first to (n−1)^{th} expansive matrixes to construct the row vector in the n^{th} row of the target H matrix so as to generate the target H matrix.
